(19) United States
(12) Patent Application Publication
(10) Pub. No.: US 2024/0170221 A1
(43) Pub. Date: May 23, 2024

(54) MULTILAYER CERAMIC CAPACITOR, CIRCUIT MODULE, AND METHOD OF MANUFACTURING CIRCUIT MODULE

(71) Applicant: Murata Manufacturing Co., Ltd., Nagaokakyo-shi (JP)

(72) Inventors: China UEDA, Nagaokakyo-shi (JP); Nobuyuki KOIZUMI, Nagaokakyo-shi (JP)

(21) Appl. No.: 18/425,862

(22) Filed: Jan. 29, 2024

Related U.S. Application Data
(63) Continuation of application No. PCT/JP2022/021066, filed on May 23, 2022.

(30) Foreign Application Priority Data
Jul. 30, 2021 (JP) 2021-125896

(51) Int. Cl. H01G 4/30; H01G 4/012; H01G 4/12; H01G 4/232; H05K 1/18; H05K 3/28

(52) U.S. Cl. CPC H01G 4/30; H01G 4/012; H01G 4/1227; H01G 4/1236; H01G 4/2325; H05K 1/181; H05K 3/284; H05K 2201/10015; H05K 2201/10977; H05K 2203/1316

(57) ABSTRACT

A multilayer ceramic capacitor includes a multilayer body including dielectric layers including a ceramic material and internal electrode layers laminated therein, and two external electrode pairs each provided on a corresponding one of two main surfaces of the multilayer body. The multilayer body includes a first capacitance portion including a first portion of the internal electrode layers and a second capacitance portion including a second portion of the internal electrode layers. The first portion of the internal electrode layers in the first capacitance portion is connected to a first of the two external electrode pairs, and the second portion of the internal electrode layers in the second capacitance portion is connected to a second of the two external electrode pairs.

### CROSS REFERENCE TO RELATED APPLICATIONS

This application claims the benefit of priority to Japanese Patent Application No. 2021-125896 filed on Jul. 30, 2021 and is a Continuation Application of PCT Application No. PCT/JP2022/021066 filed on May 23, 2022. The entire contents of each application are hereby incorporated herein by reference.

### BACKGROUND OF THE INVENTION

### 1. Field of the Invention

The present invention relates to multilayer ceramic capacitors, circuit modules including the same, and methods of manufacturing circuit modules.

### 2. Description of the Related Art

Japanese Unexamined Patent Application Publication No. 2016-76582 discloses multilayer ceramic capacitors. Such multilayer ceramic capacitors each include a multilayer body in which a plurality of dielectric layers including a ceramic material and a plurality of internal electrode layers are laminated, and external electrodes provided on end surfaces of the multilayer body.

In a circuit module in which electronic circuit components including such multilayer ceramic capacitors are mounted on a circuit board, there is a demand for a reduction in thickness. Therefore, there is also a demand for a thin layered ceramic capacitor. However, the dielectric layers and the internal electrode layers of the multilayer ceramic capacitor are extremely thin. Therefore, the reduction in thickness of each of the multilayer ceramic capacitors, i.e., the reduction in the number of the dielectric layers and the internal electrode layers, results in a decrease in bending strength and being difficult in handling.

### SUMMARY OF THE INVENTION

Example embodiments of the present invention provide multilayer ceramic capacitors that are each able to be reduced in thickness when a circuit module is mounted without reducing the bending strength as a component, circuit modules including such multilayer ceramic capacitors, and methods of manufacturing circuit modules.

An example embodiment of the present invention provides a multilayer ceramic capacitor including a multilayer body including a plurality of dielectric layers including a ceramic material and a plurality of internal electrode layers laminated therein, two main surfaces opposed to each other in a thickness direction, two lateral surfaces opposed to each other in a width direction intersecting the thickness direction, and two end surfaces opposed to each other in a length direction intersecting the thickness direction and the width direction, and two external electrode pairs each provided on a corresponding one of the two main surfaces of the multilayer body. The multilayer body includes a first capacitance portion including a first portion of the plurality of internal electrode layers and in which adjacent internal electrode layers of the first portion of the plurality of internal electrode layers are opposed to each other, and a second capacitance portion including a second portion other than the first portion of the plurality of internal electrode layers and in which adjacent internal electrode layers of the second portion of the plurality of internal electrode layers are opposed to each other. The first portion of the plurality of internal electrode layers in the first capacitance portion is connected to a first of the two external electrode pairs, and the second portion of the plurality of internal electrode layers in the second capacitance portion is connected to a second of the two external electrode pairs.

An example embodiment of the present invention provides a circuit module including a circuit board on which electronic circuit components are mounted. The circuit module includes the circuit board, a multilayer ceramic capacitor according to an example embodiment of the present invention included in the electronic circuit components mounted on the circuit board, and a resin mold provided around the multilayer ceramic capacitor. A portion of the multilayer ceramic capacitor in a thickness direction is removed such that the multilayer ceramic capacitor includes either one of a first capacitance portion or a second capacitance portion, and a surface roughness of one of the two main surfaces of the multilayer ceramic capacitor opposite to the circuit board is larger than a surface roughness of a multilayer body of the multilayer ceramic capacitor opposed to the resin mold provided around the multilayer ceramic capacitor.

An example embodiment of the present invention provides a method of manufacturing a circuit module according to an example embodiment of the present invention. The method includes mounting a multilayer ceramic capacitor included in electronic circuit components on a circuit board, filling an area around the multilayer ceramic capacitor with a resin mold, and polishing the multilayer ceramic capacitor and the resin mold in the thickness direction.

According to example embodiments of the present invention, it is possible to provide multilayer ceramic capacitors that are each able to be reduced in thickness when a circuit module is mounted without reducing the bending strength as a component. Further, according to example embodiments of the present invention, it is possible to provide circuit modules which each are able to be reduced in thickness with such multilayer ceramic capacitors, and methods of manufacturing such circuit modules.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a multilayer ceramic capacitor according to an example embodiment of the present invention.

FIG. 2 is a cross-sectional view taken along the line II-II of the multilayer ceramic capacitor shown in FIG. 1.

FIG. 3A is a cross-sectional view taken along the line IIIA-IIIA of the multilayer ceramic capacitor shown in FIG. 2.

FIG. 3B is a cross-sectional view of the multilayer ceramic capacitor shown in FIG. 2, taken along the line IIIB-IIIB.

FIG. 4 is a perspective view of internal electrode layers in the multilayer ceramic capacitor shown in FIGS. 1 to 3B.

FIG. 5A is a cross-sectional view of a circuit module according to an example embodiment of the present invention.

FIG. 5B is a side view of the multilayer ceramic capacitor after polishing in the circuit module shown in FIG. 5A.

FIG. 5C is a perspective view of the multilayer ceramic capacitor after polishing in the circuit module shown in FIG. 5A.

FIG. 6A is a cross-sectional view of the circuit module after polishing in an example of a manufacturing process of the circuit module shown in FIG. 5A.

FIG. 6B is a side view of the multilayer ceramic capacitor before polishing in the circuit module before polishing shown in FIG. 6A.

FIG. 6C is a perspective view of a multilayer ceramic capacitor before polishing in the circuit module before polishing shown in FIG. 6A.

FIG. 7 is a perspective view of a multilayer ceramic capacitor according to a modified example of an example embodiment of the present invention.

FIG. 8 is a cross-sectional view taken along the line VIII-VIII of the multilayer ceramic capacitor shown in FIG. 7.

FIG. 9A is a cross-sectional view taken along the line IXA-IXA of the multilayer ceramic capacitor shown in FIG. 8.

FIG. 9B is a cross-sectional view taken along the line IXB-IXB of the multilayer ceramic capacitor shown in FIG. 8.

FIG. 10 is a perspective view of internal electrode layers in the multilayer ceramic capacitor shown in FIGS. 7 to 9B.

FIG. 11 is a perspective view of a multilayer ceramic capacitor according to a modified example of an example embodiment of the present invention.

FIG. 12 is a cross-sectional view taken along the line XII-XII of the multilayer ceramic capacitor shown in FIG. 11.

FIG. 13 is a cross-sectional view taken along the line XIII-XIII of the multilayer ceramic capacitor shown in FIG. 11.

FIG. 14 is a perspective view of internal electrode layers in the multilayer ceramic capacitor shown in FIGS. 11 to 13.

### DETAILED DESCRIPTION OF THE EXAMPLE EMBODIMENTS

Example embodiments of the present invention will now be described with reference to the accompanying drawings. In the drawings, the same or corresponding portions are denoted by the same reference numerals.

### Multilayer Ceramic Capacitor

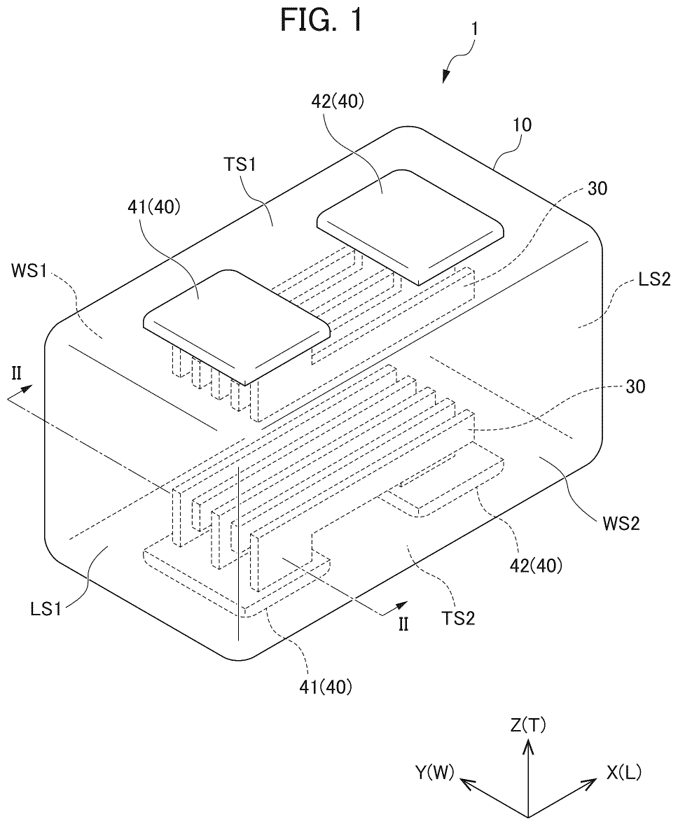

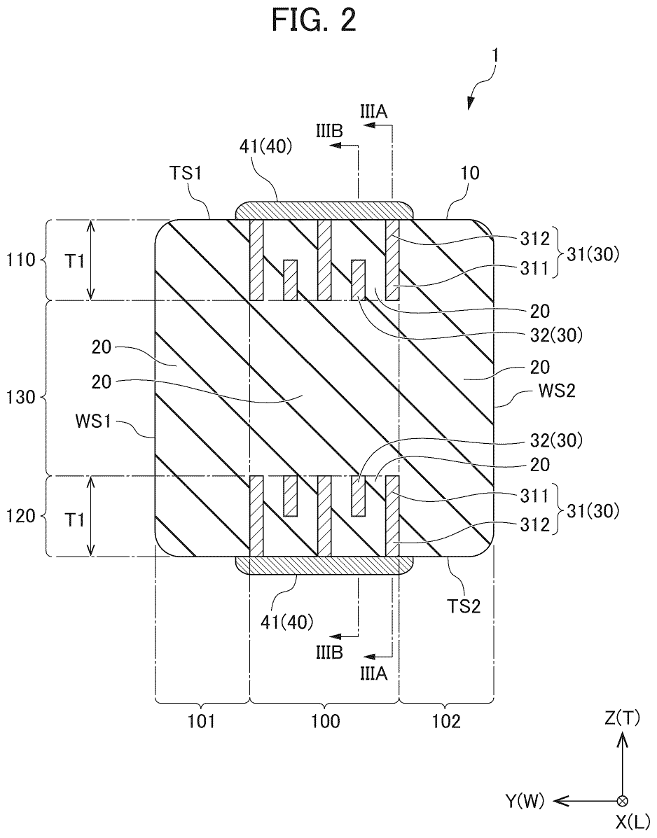

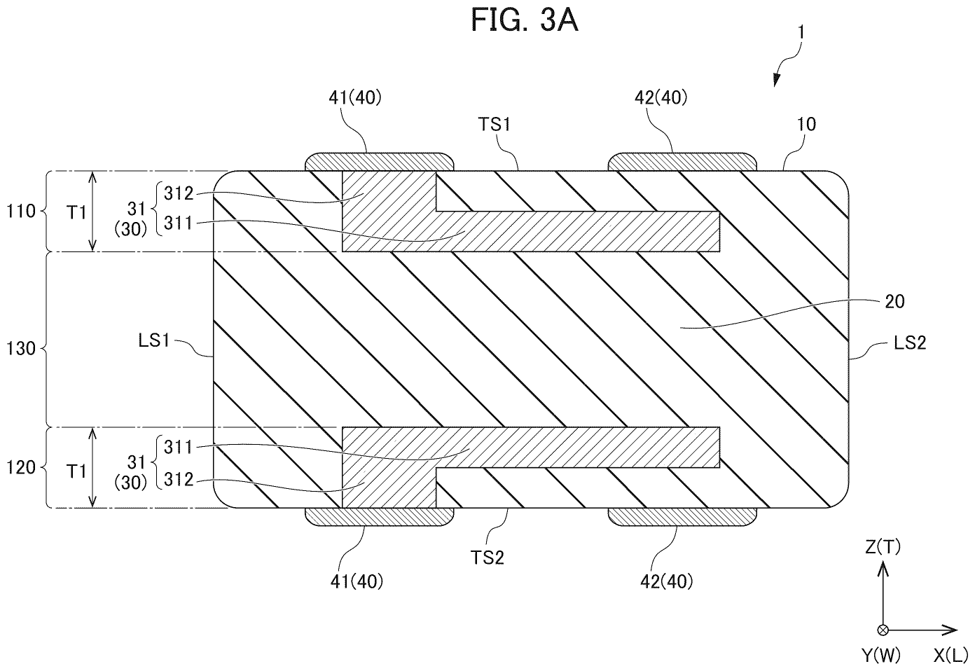

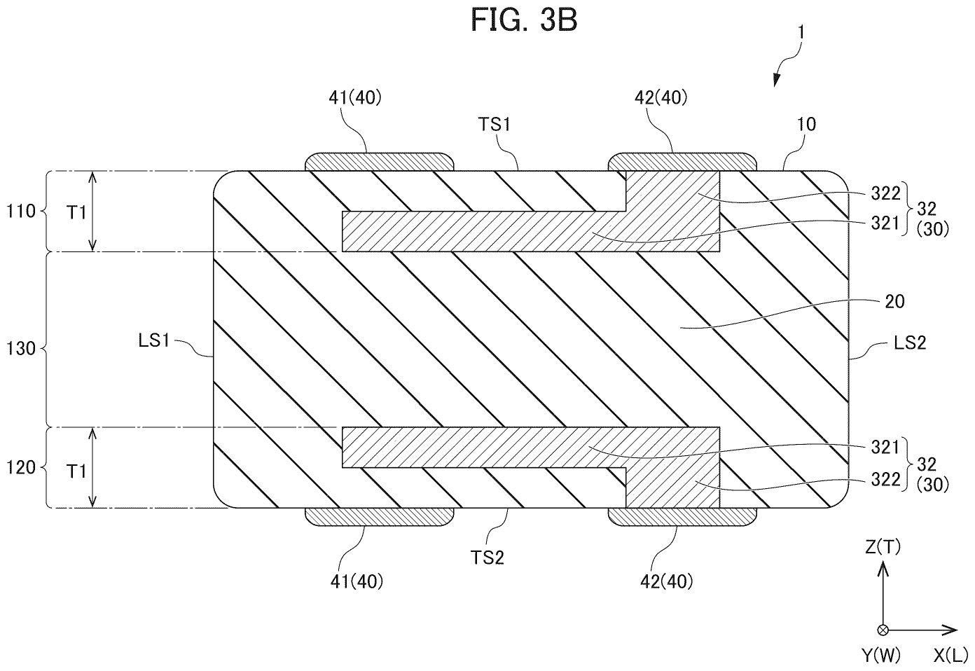

FIG. 1 is a perspective view of a multilayer ceramic capacitor according to an example embodiment of the present invention, and FIG. 2 is a cross-sectional view of the multilayer ceramic capacitor shown in FIG. 1 taken along the line II-II. FIG. 3A is a cross-sectional view taken along the line IIIA-IIIA of the multilayer ceramic capacitor shown in FIG. 2, and FIG. 3B is a cross-sectional view taken along the line IIIB-IIIB of the multilayer ceramic capacitor shown in FIG. 2. The multilayer ceramic capacitor 1 shown in FIGS. 1 to 3B includes a multilayer body 10 and two external electrode pairs 40. Each of the two external electrode pairs 40 includes a first external electrode 41 and a second external electrode 42.

FIGS. 1 to 3B each show XYZ orthogonal coordinate systems. The X direction refers to the length direction L of the multilayer ceramic capacitor 1 and the multilayer body 10, the Y direction refers to the width direction W of the multilayer ceramic capacitor 1 and the multilayer body 10, and the Z direction refers to the thickness direction T of the multilayer ceramic capacitor 1 and the multilayer body 10. Thus, the cross section shown in FIG. 2 is also referred to as a WT cross section, and the cross section shown in FIGS. 3A and 3B is also referred to as an LT cross section. The length direction L, the width direction W, and the thickness direction T are not necessarily orthogonal to each other, and may intersect each other.

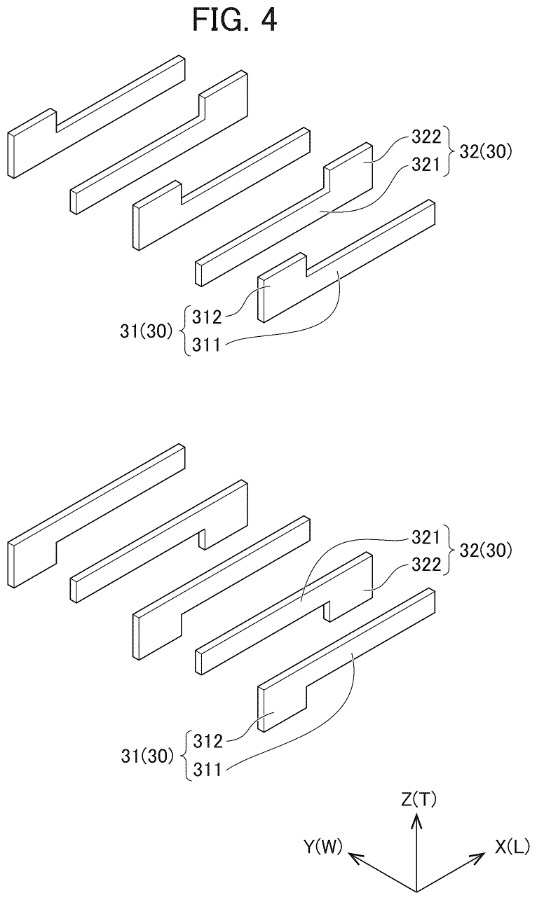

FIG. 4 is a perspective view of internal electrode layers in the multilayer ceramic capacitor shown in FIGS. 1 to 3B, and FIG. 1 shows the internal electrode layers in FIG. 4 and one of the two external electrode pairs in a transparent manner.

The multilayer body 10 has a rectangular or substantially rectangular parallelepiped shape, and includes a first main surface TS1 and a second main surface TS2 opposed to each other in the thickness direction T, a first lateral surface WS1 and a second lateral surface WS2 opposed to each other in the width direction W, and a first end surface LS1 and a second end surface LS2 opposed to each other in the length direction L. The corner portions and ridge portions of the multilayer body 10 are preferably rounded. Each of the corner portions is a portion where the three surfaces of the multilayer body 10 intersect, and each of the ridge portions is a portion where the two surfaces of the multilayer body 10 intersect.

As shown in FIGS. 2, 3A and 3B, the multilayer body 10 includes a plurality of dielectric layers 20 and a plurality of internal electrode layers 30 laminated in the width direction W. With such a configuration, the multilayer body 10 includes an inner layer portion 100, and a first outer layer portion 101 and a second outer layer portion 102 that sandwich the inner layer portion 100 in the width direction W, i.e., the lamination direction.

The multilayer body 10 includes a first capacitance portion 110, a second capacitance portion 120, and a non-capacitance portion 130 in the thickness direction T. The first capacitance portion 110 is provided adjacent to the first main surface TS1 of the multilayer body 10, and the second capacitance portion 120 is provided adjacent to the second main surface TS2 of the multilayer body 10. The non-capacitance portion 130 is positioned between the first capacitance portion 110 and the second capacitance portion 120.

The inner layer portion 100 includes a portion of the plurality of dielectric layers 20 and the plurality of internal electrode layers 30. More specifically, the first capacitance portion 110 in the inner layer portion 100 includes a portion of the plurality of dielectric layers 20 and a portion of the plurality of internal electrode layers 30. The second capacitance portion 120 in the inner layer portion 100 includes a portion of the plurality of dielectric layers 20 and a portion of the plurality of internal electrode layers 30 other than a portion for the first capacitance portion 110. In the first capacitance portion 110 and the second capacitance portion 120, adjacent internal electrode layers 30 are opposed to each other with the dielectric layer 20 interposed therebetween. The first capacitance portion 110 and the second capacitance portion 120 are portions that generate capacitance and each substantially define and function as capacitors. On the other hand, the non-capacitance portion 130 in the inner layer portion 100 does not include the internal electrode layers 30, and includes a plurality of dielectric layers 20.

The first outer layer portion 101 is provided adjacent to the first lateral surface WS1 of the multilayer body 10, and the second outer layer portion 102 is provided adjacent to the second lateral surface WS2 of the multilayer body 10. More specifically, the first outer layer portion 101 is provided between the internal electrode layer 30 closest to the first lateral surface WS1 of the plurality of internal electrode layers 30 and the first lateral surface WS1, and the second outer layer portion 102 is provided between the internal electrode layer 30 closest to the second lateral surface WS2 of the plurality of internal electrode layers 30 and the second lateral surface WS2. The first outer layer portion 101 and the second outer layer portion 102 do not include the internal electrode layer 30, but each include a portion of the plurality of dielectric layers 20 other than a portion for the inner layer portion 100. Each of the first outer layer portion 101 and the second outer layer portion 102 defines and functions as a protective layer of the first capacitance portion 110 and the second capacitance portion 120 in the inner layer portion 100.

As a material of the dielectric layer 20, for example, a dielectric ceramic including BaTiO₃, CaTiO₃, SrTiO₃, CaZrO₃, or the like as a main component can be used. As a material of the dielectric layer 20, for example, a Mn compound, an Fe compound, a Cr compound, a Co compound, a Ni compound, or the like may be added as a subcomponent.

The thickness of the dielectric layer 20 is not particularly limited, but is preferably, for example, about 0.4 μm or more and about 2.0 μm or less. The number of dielectric layers 20 is not particularly limited, but is preferably, for example, 50 or more and 450 or less. The number of the dielectric layers 20 is the total number of the number of the dielectric layers of the inner layer portion and the number of the dielectric layers of the outer layer portion.

As shown in FIGS. 2 to 4, each of the first capacitance portion 110 and the second capacitance portion 120 includes a plurality of first internal electrode layers 31 and a plurality of second internal electrode layers 32 as a plurality of internal electrode layers 30. The plurality of first internal electrode layers 31 each include a counter electrode portion 311 and an extension electrode portion 312, and the plurality of second internal electrode layers 32 each include a counter electrode portion 321 and an extension electrode portion 322.

In the first capacitance portion 110, the counter electrode portion 311 and the counter electrode portion 321 are opposed to each other with the dielectric layer 20 interposed therebetween in the lamination direction of the multilayer body 10, that is, in the width direction W. The shapes of the counter electrode portion 311 and the counter electrode portion 321 are not particularly limited, and may be rectangular or substantially rectangular, for example. The counter electrode portion 311 and the counter electrode portion 321 are portions which substantially define and function as capacitors to generate capacitances.

In the first capacitance portion 110, the extension electrode portion 312 extends from a portion of the counter electrode portion 311 adjacent to the first end surface LS1 of the multilayer body 10 toward the first main surface TS1 of the multilayer body 10, and is exposed at the first main surface TS1. The extension electrode portion 322 extends from a portion of the counter electrode portion 321 adjacent to the second end surface LS2 of the multilayer body 10 toward the first main surface TS1 of the multilayer body 10, and is exposed at the first main surface TS1. The shapes of the extension electrode portion 312 and the extension electrode portion 322 are not particularly limited, and may be rectangular or substantially rectangular, for example.

With such a configuration, in the first capacitance portion 110, each of the first internal electrode layers 31 is connected to the first external electrode 41 of the external electrode pair 40 provided on the first main surface TS1 of the multilayer body 10, and is spaced apart from the second external electrode 42 of the external electrode pair 40 provided on the first main surface TS1. Each of the second internal electrode layers 32 is connected to the second external electrode 42 of the external electrode pair 40 provided on the first main surface TS1 of the multilayer body 10, and is spaced apart from the first external electrode 41 of the external electrode pair 40 provided on the first main surface TS1.

Similarly, in the second capacitance portion 120, the counter electrode portion 311 and the counter electrode portion 321 are opposed to each other via the dielectric layer 20 in the lamination direction of the multilayer body 10, i.e., in the width direction W. In the second capacitance portion 120, the extension electrode portion 312 extends from a portion of the counter electrode portion 311 adjacent to the first end surface LS1 of the multilayer body 10 toward the second main surface TS2 of the multilayer body 10, and is exposed at the second main surface TS2. The extension electrode portion 322 extends from a portion of the counter electrode portion 321 adjacent to the second end surface LS2 of the multilayer body 10 toward the second main surface TS2 of the multilayer body 10, and is exposed on the second main surface TS2.

Thus, in the second capacitance portion 120, each of the first internal electrode layers 31 is connected to the first external electrode 41 of the external electrode pair 40 provided on the second main surface TS2 of the multilayer body 10, and is spaced apart from the second external electrode 42 of the external electrode pair 40 provided on the second main surface TS2. Further, each of the second internal electrode layers 32 is connected to the second external electrode 42 of the external electrode pair 40 provided on the second main surface TS2 of the multilayer body 10, and is spaced apart from the first external electrode 41 in the external electrode pair 40 provided on the second main surface TS2.

The plurality of internal electrode layers 30 in the first capacitance portion 110 and the plurality of internal electrode layers 30 in the second capacitance portion 120 may be plane symmetrical with respect to the middle in the thickness direction T. Alternatively, the plurality of internal electrode layers 30 in the first capacitance portion 110 and the plurality of internal electrode layers 30 in the second capacitance portion 120 may be rotationally symmetrical with respect to the middle in the thickness direction T and the middle in the width direction W. Further, when the thickness in the width direction W of the first outer layer portion 101 and the thickness in the width direction W of the second outer layer portion 102 are different, the plurality of internal electrode layers 30 in the first capacitance portion 110 and the plurality of internal electrode layers 30 in the second capacitance portion 120 may be rotationally symmetrical with respect to the middle in the thickness direction T of the multilayer body 10 and the middle in the width direction W of the inner layer portion 100 of the multilayer body 10.

The thickness T1 of the internal electrode layer 30 in the thickness direction T of the first capacitance portion 110, in other words, the thickness T1 of the internal electrode layer 30 in the first capacitance portion 110 from the first main surface TS1, is preferably, for example, about 25 μm or more and about 70 μm or less. The thickness T1 of the internal electrode layer 30 in the thickness direction T of the second capacitance portion 120, in other words, the thickness T1 of the internal electrode layer 30 in the second capacitance portion 120 from the second main surface TS2, is preferably, for example, about 25 μm or more and about 70 μm or less.

Each of the first internal electrode layers 31 and the second internal electrode layers 32 includes, for example, metal Ni as a main component. Further, each of the first internal electrode layers 31 and the second internal electrode layers 32 may include, for example, at least one selected from metals such as Cu, Ag, Pd, and Au or alloys including at least one of these metals such as Ag—Pd alloy as a main component, or may include a component other than the main component. Further, each of the first internal electrode layers 31 and the second internal electrode layers 32 may include dielectric particles including the same composition as the ceramic included in the dielectric layer 20 as components other than the main component. In this specification, the metal of the main component is defined as a metal component having the highest weight %.

The thickness of each of the first internal electrode layers 31 and the second internal electrode layers 32 is not particularly limited, but are preferably, for example, about 0.2 μm or more and about 1.0 μm or less. The number of the first internal electrode layers 31 and the second internal electrode layers 32 is not particularly limited, but is preferably, for example, 2 or more and 430 or less.

The dimensions of the multilayer body 10 described above are not particularly limited, but, for example, the length in the length direction L is preferably about 0.2 mm or more and about 0.6 mm or less, the width in the width direction W is preferably about 0.1 mm or more and about 0.3 mm or less, and the thickness in the thickness direction T is preferably about 0.1 mm or more and about 0.3 mm or less.

One of the two external electrodes pairs 40 is provided on the first main surface TS1 of the multilayer body 10, and the other of external electrode pairs 40 is provided on the second main surface TS2 of the multilayer body 10. Each external electrode pair 40 includes a first external electrode 41 and a second external electrode 42.

The first external electrode 41 of one of the two external electrode pairs 40 is provided adjacent to the first end surface LS1 on the first main surface TS1 of the multilayer body 10, and the second external electrode 42 of the one of the two external electrode pairs 40 is provided adjacent to the second end surface LS2 on the first main surface TS1 of the multilayer body 10. The first external electrode 41 is connected to the first internal electrode layers 31 in the first capacitance portion 110, and the second external electrode 42 is connected to the second internal electrode layers 32 in the first capacitance portion 110.

The first external electrode 41 of the other of the two external electrode pairs 40 is provided adjacent to the first end surface LS1 on the second main surface TS2 of the multilayer body 10, and the second external electrode 42 of the other of the two external electrode pairs 40 is provided adjacent to the second end surface LS2 on the second main surface TS2 of the multilayer body 10. The first external electrode 41 is connected to the first internal electrode layers 31 in the second capacitance portion 120, and the second external electrode 42 is connected to the second internal electrode layers 32 in the second capacitance portion 120.

The first external electrode 41 and the second external electrode 42 are each preferably, for example, a metal layer including plating. That is, the first external electrode 41 and the second external electrode 42 are each preferably, for example, a metal layer including only a plated layer. The metal layer including plating includes, for example, at least one of Cu, Ni, Ag, Pd, or Au, or an alloy such as Ag—Pd alloy.

The metal layer including plating may include a plurality of layers. For example, a three-layer configuration of Cu plating, Ni plating, and Sn plating is preferable. The Ni plated layer can prevent the base electrode layer from being eroded by the solder when the ceramic electronic component is mounted, and the Sn plated layer can improve wettability of the solder when the ceramic electronic component is mounted and thus can facilitate mounting. The thickness per layer of the metal layer consisting of plating is not particularly limited, and may be, for example, about 1 μm or more and about 10 μm or less.

The first external electrode 41 and the second external electrode 42 each may include a base layer of a metal layer including plating. The base layer may be formed by a thin film forming method such as, for example, sputtering or vapor deposition, and may be a thin film layer including metal particles deposited thereon and having a thickness of about 1 μm or less. The entire thickness of each of the first external electrodes 41 and the second external electrodes 42 is preferably, for example, about 4 μm or more and about 16 μm or less.

Alternatively, the base layer may be a fired layer including metal and glass, for example. Examples of the glass include glass components including at least one of B, Si, Ba, Mg, Al, Li, and the like. As a specific example, borosilicate glass can be used. The metal includes Cu as a main component. The metal may include at least one selected from a metal such as Ni, Ag, Pd, or Au or an alloy such as Ag—Pd alloy as a main component, or may include a component other than the main component.

The fired layer is a layer obtained by applying an electrically conductive paste including a metal and glass to a multilayer body by, for example, a dipping method, and firing the multilayer body. The fired layer may be fired after firing the internal electrode layers, or may be fired simultaneously with the internal electrode layers. The fired layer may include a plurality of layers.

Alternatively, the base layer may be, for example, a resin layer including electrically conductive particles and a thermosetting resin. The resin layer may be formed on the fired layer described above, or may be formed directly on the multilayer body without forming the fired layer.

The resin layer is a layer obtained by, for example, applying an electrically conductive paste including conductive particles and a thermosetting resin to a multilayer body by a coating method, and firing the multilayer body. The resin layer may be fired after firing the internal electrode layers, or may be fired simultaneously with the internal electrode layers. The resin layer may include a plurality of layers.

The thickness per layer of the base layer as the fired layer or the resin layer is not particularly limited, and may be, for example, about 1 μm or more and about 10 μm or less.

### Circuit Module

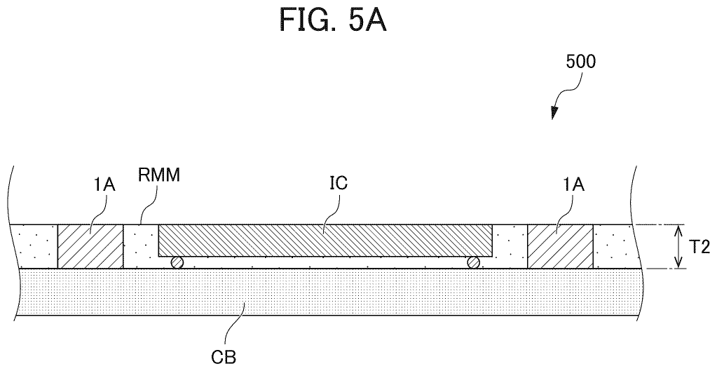

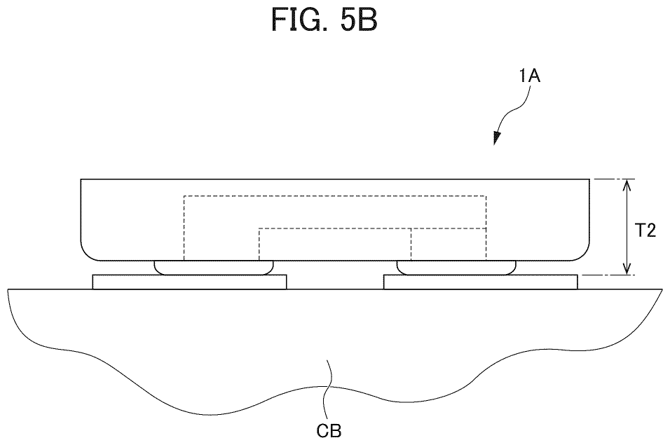

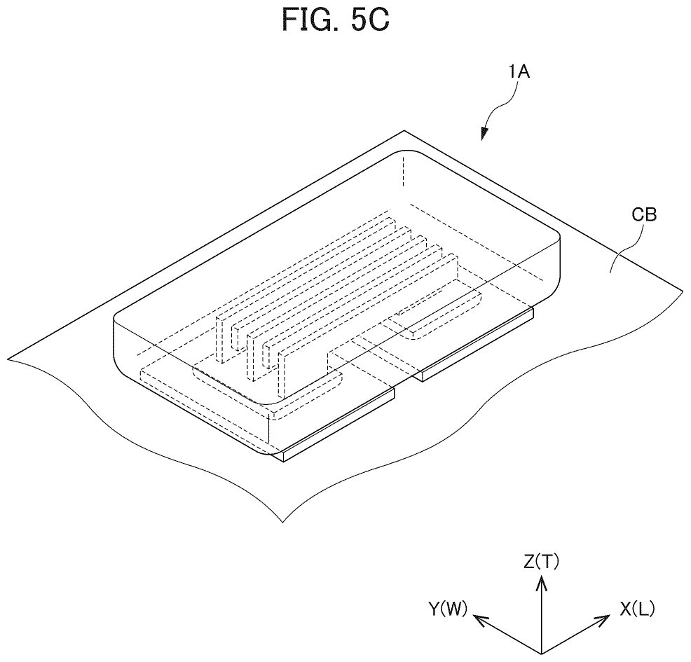

Next, a circuit module according to an example embodiment of the present invention in which the above-described multilayer ceramic capacitor 1 is mounted will be described. FIG. 5A is a cross-sectional view of an example of a circuit module according to the present example embodiment. FIG. 5B is a side view of the multilayer ceramic capacitor after polishing in the circuit module shown in FIG. 5A. FIG. 5C is a perspective view of the multilayer ceramic capacitor after polishing in the circuit module shown in FIG. 5A. After polishing, the polished surface has a larger surface roughness than the lateral surfaces WS1 and WS2 and the end surfaces LS1 and LS2. The surface roughness RA is measured by, for example, a laser displacement meter or the like.

As shown in FIG. 5A, a circuit module 500 includes a circuit board CB, an electronic circuit component, and a resin molded member RMM. Although FIG. 5A illustrates multilayer ceramic capacitors 1A and an integrated circuit IC as electronic circuit components, the present invention is not limited thereto, and various electronic circuit components can be provided. For example, the electronic circuit component may include a capacitor, an inductor, a resistor, a semiconductor IC (switch IC, LNA IC, controller IC, PA IC, etc.), a filter (SAW, BAW, LC filter, etc.), and the like.

The electronic circuit components, for example, the multilayer ceramic capacitors 1A and the integrated circuit IC, are mounted on one main surface of the circuit board CB. The periphery of the multilayer ceramic capacitors 1A and the integrated circuit IC is filled with the resin mold RMM. With such a configuration, the resin mold RMM is provided around the multilayer ceramic capacitors 1A and the integrated circuit IC. An electronic circuit component may also be mounted on the other main surface of the circuit board CB.

As described later, the multilayer ceramic capacitors 1A and the integrated circuit IC are polished and removed after being molded by the resin mold RMM. With such a configuration, the main surface of the multilayer ceramic capacitor 1A opposite to the circuit board CB and the main surface of the resin mold RMM opposite to the circuit board CB are aligned or flush with each other in the thickness direction T. The surface roughness (polished surface) of the main surface of the multilayer ceramic capacitor 1A opposite to the circuit board CB is larger than the surface roughness of the multilayer ceramic capacitor 1A (the lateral surfaces WS1 and WS2 and the end surfaces LS1 and LS2) opposed to the resin mold RMM provided around the multilayer ceramic capacitor 1A.

Further, as shown in FIGS. 5B and 5C, the multilayer ceramic capacitor 1A is in a processed such that the multilayer ceramic capacitor 1 described above is polished in the thickness direction T such that a portion of the multilayer ceramic capacitor 1A in the thickness direction T is removed. More specifically, the multilayer ceramic capacitor 1A includes either one of the first capacitance portion 110 or the second capacitance portion 120 in the above-described multilayer ceramic capacitor 1. That is, in the multilayer ceramic capacitor 1A, either one of the first capacitance portion 110 or the second capacitance portion 120 in the above-described multilayer ceramic capacitor 1 is removed, and only the remaining other one of the first capacitance portion 110 or the second capacitance portion 120 is included.

The ridge portion where the main surface of the multilayer ceramic capacitor 1A opposite to the circuit board CB and the end surfaces LS1 and LS2 intersect, and the ridge portion where the main surface of the multilayer ceramic capacitor 1A opposite to the circuit board CB and the lateral surfaces WS1 and WS2 intersect are not chamfered, and these ridge portions are not rounded. More specifically, the radius of curvature of these ridge portions is, for example, about 10 μm or less. The radius of curvature of the ridge portion where the main surfaces TS1 and TS2 of the multilayer body 10 intersect with the end surfaces LS1 and LS2, and the ridge portion where the main surfaces TS1 and TS2 of the multilayer body 10 intersect with the lateral surfaces WS1 and WS2, i.e., the chamfered ridge portion, is about 10 μm or more and about 35 μm or less, for example. The thickness T2 of the multilayer ceramic capacitor 1A from the circuit board CB is preferably, for example, about 29 μm or more and about 86 μm or less.

### Method of Manufacturing Multilayer Ceramic Capacitor

Next, an n example of a method of manufacturing the multilayer ceramic capacitor 1 will be described. First, a dielectric sheet for preparing the dielectric layers 20 and an electrically conductive paste for preparing the internal electrode layer 30 are prepared. The dielectric sheet and the electrically conductive paste include a binder and a solvent. As the binder and the solvent, well-known materials can be used.

Next, an internal electrode pattern is formed on the dielectric sheet by printing an electrically conductive paste on the dielectric sheet in a predetermined pattern, for example. As a method of forming the internal electrode pattern, for example, screen printing, gravure printing, or the like can be used.

Next, a predetermined number of dielectric sheets for preparing the second outer layer portion 102 on which no internal electrode pattern is printed are laminated. A dielectric sheet for preparing the inner layer portion 100 on which the internal electrode pattern is printed is sequentially laminated thereon. A predetermined number of dielectric sheets for preparing the first outer layer portion 101 on which no internal electrode pattern is printed are laminated thereon. Thus, a multilayer sheet is fabricated.

Next, the multilayer sheet is pressed in the lamination direction by, for example, hydrostatic pressing to form a multilayer block. Next, the multilayer block is cut into a predetermined size, and the multilayer chip is cut out. At this time, the corner portions and ridge portions of the multilayer chip are rounded by, for example, barrel polishing or the like. Next, the multilayer chip is fired to prepare a multilayer body 10. The firing temperature is preferably, for example, about 900° C. or higher and about 1400° C. or lower, although it depends on the material of the dielectric and the internal electrode.

Next, a metal layer including plating is formed on the first main surface TS1 of the multilayer body 10 to form one external electrode pair 40. Further, a metal layer including plating is formed on the second main surface TS2 of the multilayer body 10 to form the other external electrode pair 40. Through the above steps, the above-described multilayer ceramic capacitor 1 is obtained.

### Method of Manufacturing Circuit Module

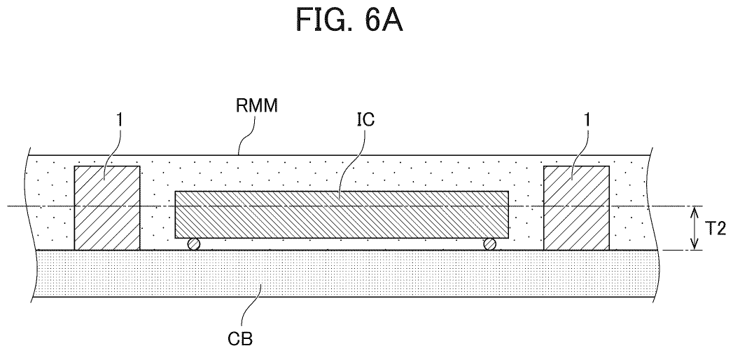

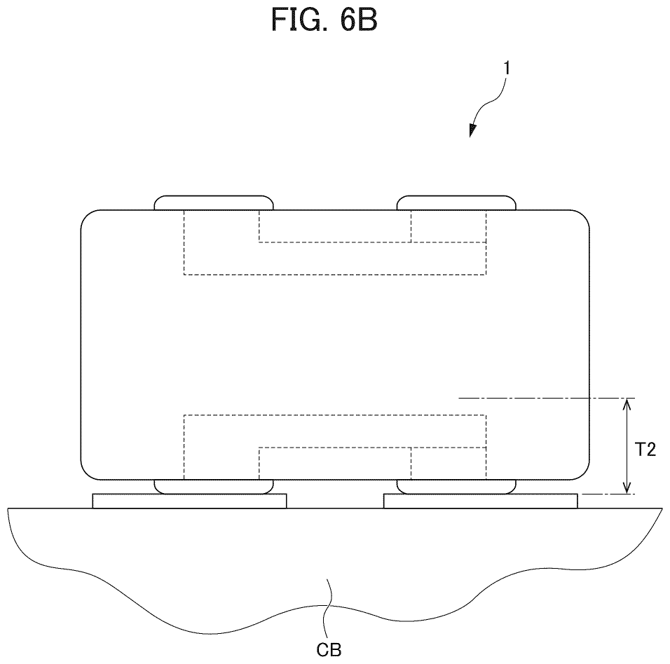

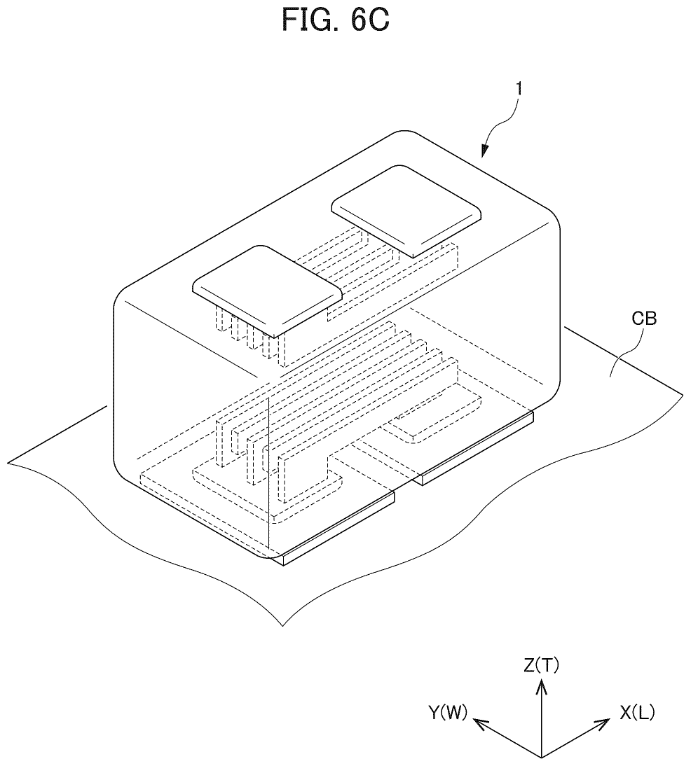

Next, an example of a method of manufacturing the circuit module 500 described above will be described. FIG. 6A is a cross-sectional circuit module after polishing in the manufacturing process of the circuit module shown in FIG. 5A. FIG. 6B is a side view of the multilayer ceramic capacitor before polishing in the circuit module before polishing shown in FIG. 6A. FIG. 6C is a perspective view of the multilayer ceramic capacitor before polishing in the circuit module before polishing shown in FIG. 6A.

First, as shown in FIG. 6A, an electronic circuit component, for example, the above-described multilayer ceramic capacitors 1 and the integrated circuit IC, are mounted on one main surface of the circuit board CB. Next, the electronic circuit components, for example, the surrounds of the multilayer ceramic capacitors 1 and the integrated circuit IC, are filled with a resin mold RMM.

Next, as shown in FIG. 5A, electronic circuit components such as, for example, the multilayer ceramic capacitors 1, the integrated circuit IC, and the resin mold RMM are polished in the thickness direction T. At this time, the exposed surface of the electronic circuit component may be remolded.

Thereafter, the electronic circuit component may be mounted on the other main surface of the circuit board CB, or the periphery of the electronic circuit component may be filled with a resin mold. The circuit module 500 shown in FIG. 5A is thereby obtained.

As described above, according to the multilayer ceramic capacitor 1 of the present example embodiment, the two capacitance portions 110 and 120 and the two external electrode pairs 40 respectively corresponding to the two capacitance portions 110 and 120 are provided. More specifically, according to the multilayer ceramic capacitor 1 of the present example embodiment, the two capacitance portions 110 and 120 are provided in the thickness direction T. Thus, by polishing and removing one capacitance portion in the thickness direction T, a thin capacitor can be obtained by the other capacitance portion. In this way, the bending strength of the component before polishing is not reduced. On the other hand, when the circuit module is mounted, the thickness can be reduced by polishing in the thickness direction T.

Further, according to the multilayer ceramic capacitor 1 of the present example embodiment, since the external electrode pair 40 is a metal layer including plating, in other words, since the fired layer or the resin layer is not included in the external electrode pair 40, it is possible to further reduce the thickness.

Further, according to the multilayer ceramic capacitor 1 of the present example embodiment, the internal electrode layers 30 in the first capacitance portion 110 and the internal electrode layers 30 in the second capacitance portion 120 are plane symmetrical or rotationally symmetrical with respect to the middle in the thickness direction T. This eliminates the need to discriminate between the front and back surfaces of the multilayer ceramic capacitor 1.

Although example embodiments of the present invention have been described above, the present invention is not limited to the example embodiments described above, and various changes and modifications thereto are possible. For example, in the above-described example embodiment, the multilayer ceramic capacitor 1 in which the two external electrode pairs 40 are provided on the first main surface TS1 and the second main surface TS2 of the multilayer body 10 is illustrated and described. However, the shape of the external electrode pairs 40 is not limited thereto, and the external electrode pairs 40 may extend from the main surface TS1 or TS2 to the end surface LS1 or LS2 (refer to Modified Example 1 described later). Further, the external electrode pairs 40 may extend from the main surface TS1 or TS2 to the lateral surface WS1 or WS2 (refer to Modified Example 2 described later).

### Modified Example 1

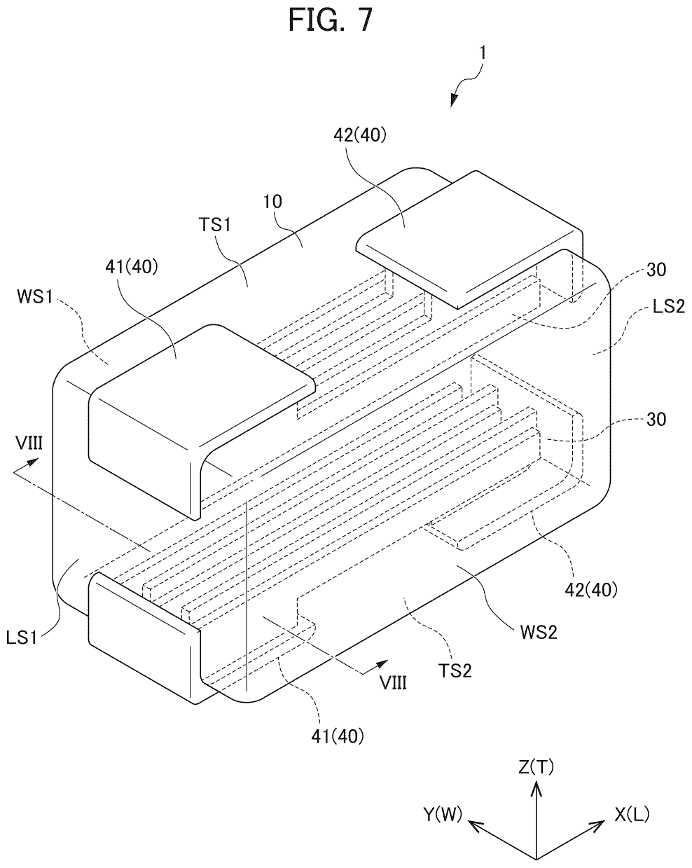

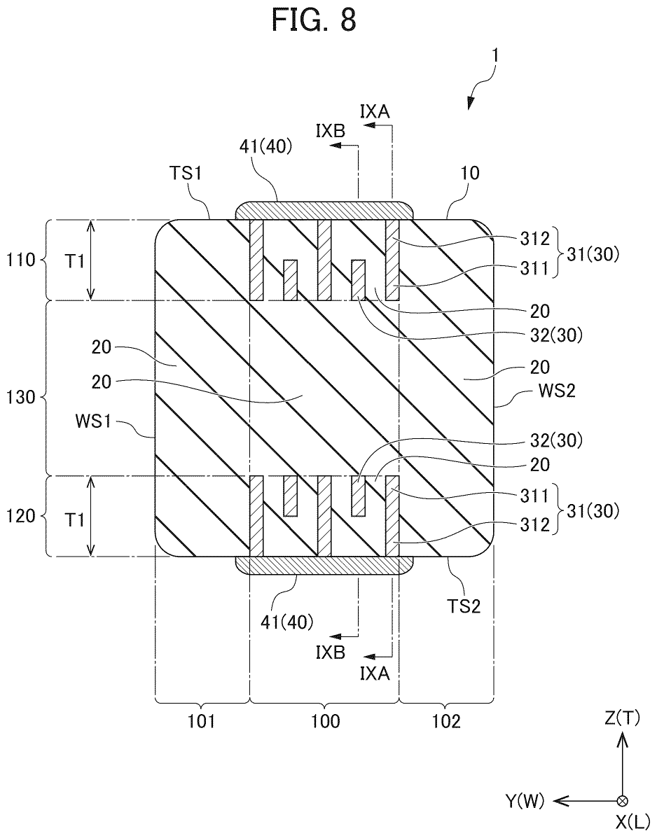

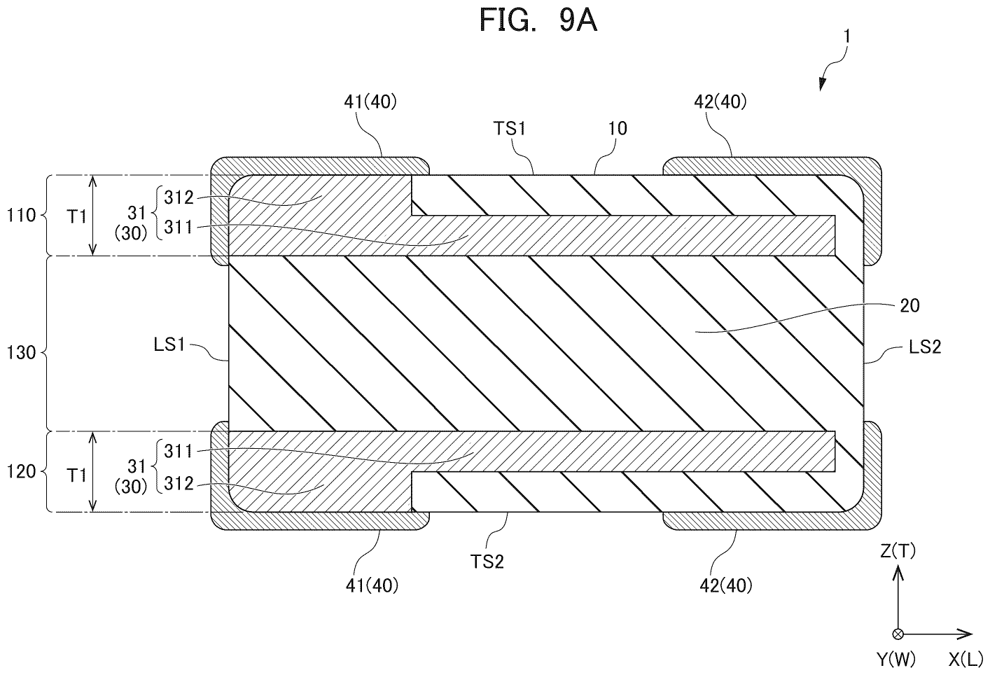

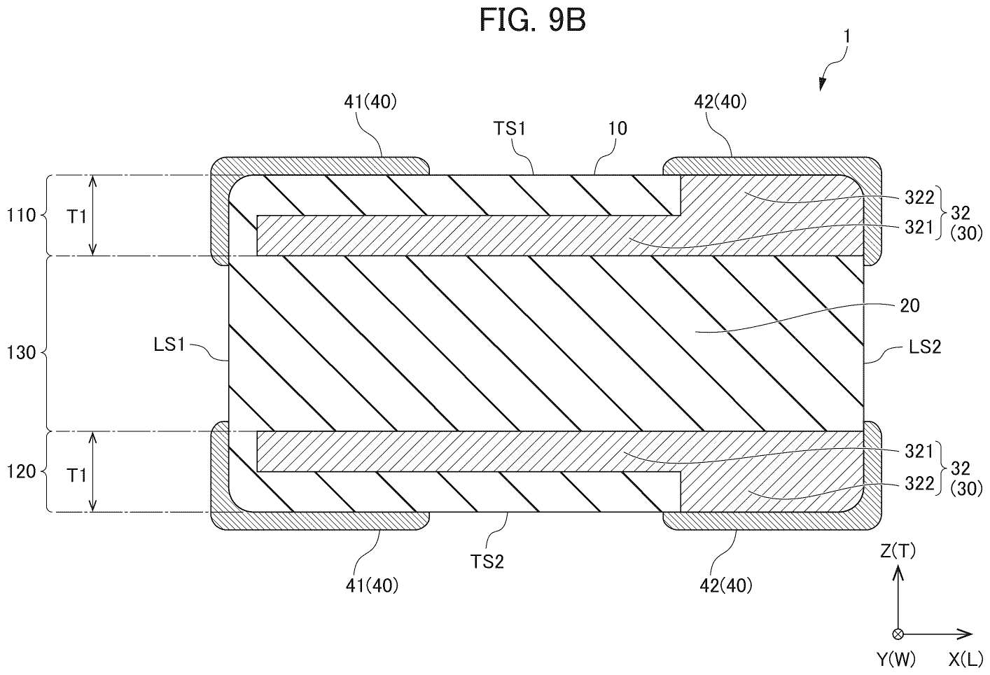

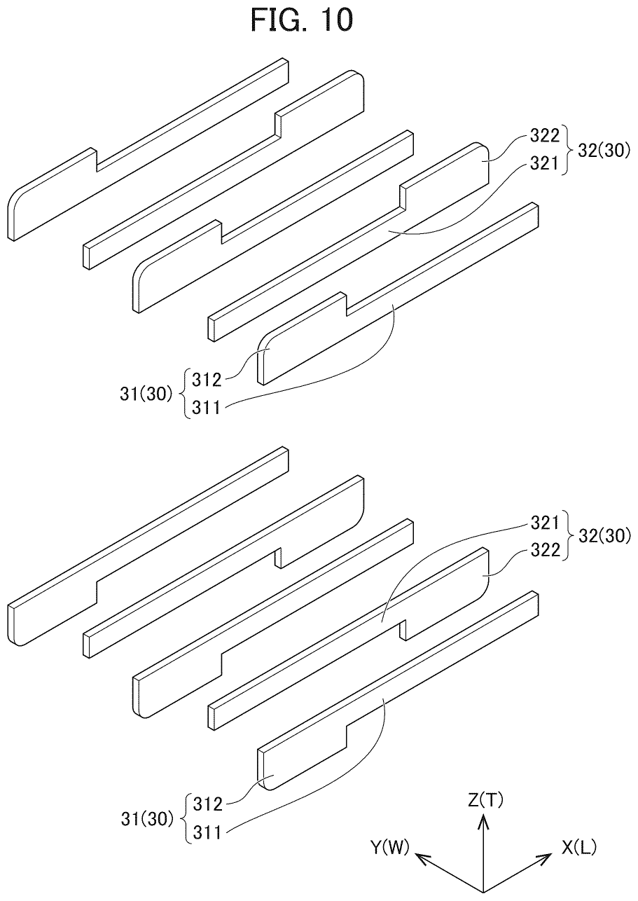

FIG. 7 is a perspective view of a multilayer ceramic capacitor according to a modified example of an example embodiment of the present invention, and FIG. 8 is a cross-sectional view of the multilayer ceramic capacitor shown in FIG. 7 taken along the line VIII-VIII. FIG. 9A is a cross-sectional view taken along the line IXA-IXA of the multilayer ceramic capacitor shown in FIG. 8, and FIG. 9B is a cross-sectional view taken along the line IXB-IXB of the multilayer ceramic capacitor shown in FIG. 8. FIG. 10 is a perspective view of the internal electrode layers in the multilayer ceramic capacitor shown in FIGS. 7 to 9B, and FIG. 7 shows the internal electrode layers shown in FIG. 10 and one of the two external electrode pairs in a transparent manner.

The multilayer ceramic capacitor 1 shown in FIGS. 7 to 9B is different from the multilayer ceramic capacitor 1 shown in FIGS. 1 to 3B in the shape of the two external electrode pairs 40, and in the shape of the internal electrode layers 30 in the first capacitance portion 110 and the second capacitance portion 120 of the multilayer body 10.

Specifically, the first external electrode 41 of one of the two external electrode pairs 40 provided on the first main surface TS1 of the multilayer body 10 may extend from the first main surface TS1 to a portion of the first end surface LS1, and the second external electrode 42 of the other one of the two external electrode pairs 40 may extend from the first main surface TS1 to a portion of the second end surface LS2. This makes it possible to improve the bonding strength by utilizing the wettability of the solder when the solder is mounted on the circuit board.

Similarly, the first external electrode 41 of the other one of the two external electrode pairs 40 provided on the second main surface TS2 of the multilayer body 10 may extend from the second main surface TS2 to a portion of the first end surface LS1, and the second external electrode 42 of the other one of the two external electrode pairs 40 may extend from the second main surface TS2 to a portion of the second end surface LS2. This makes it possible to improve the bonding strength by utilizing the wettability of the solder when the solder is mounted on the circuit board.

In the first capacitance portion 110, the first internal electrode layers 31, more specifically, the extension electrode portions 312, each extend from a portion of the counter electrode portion 311 adjacent to the first end surface LS1 of the multilayer body 10 toward the first end surface LS1 of the multilayer body 10, and is exposed at the first end surface LS1. Thus, the first internal electrode layers 31 and the first external electrode 41 are connected not only to the first main surface TS1, but also to the first end surface LS1 and the ridge portion where the first main surface TS1 and the first end surface LS1 intersect. Therefore, it is possible to increase the contact area between each of the first internal electrode layers 31 and the first external electrode 41, and it is also possible to reduce the contact resistance between each of the first internal electrode layers 31 and the first external electrode 41.

Further, in the first capacitance portion 110, the second internal electrode layers 32, more specifically, the extension electrode portions 322, each extend from the portion of the counter electrode portion 321 adjacent to the second end surface LS2 of the multilayer body 10 toward the second end surface LS2 of the multilayer body 10, and is exposed at the second end surface LS2. Thus, the second internal electrode layers 32 and the second external electrode 42 are connected not only to the first main surface TS1, but also to the second end surface LS2 and the ridge portion of the multilayer body 10 where the first main surface TS1 and the second end surface LS2 intersect. Therefore, it is possible to increase the contact area between each of the second internal electrode layers 32 and the second external electrode 42, and it is possible to reduce the contact resistance between each of the second internal electrode layers 32 and the second external electrode 42.

Similarly, in the second capacitance portion 120, the first internal electrode layers 31, more specifically, the extension electrode portions 312, each extends from a portion of the counter electrode portion 311 adjacent to the first end surface LS1 of the multilayer body 10 toward the first end surface LS1 of the multilayer body 10, and is exposed at the first end surface LS1. Thus, the first internal electrode layers 31 and the first external electrode 41 are connected not only to the second main surface TS2, but also to the first end surface LS1 and the ridge portion of the multilayer body 10 where the second main surface TS2 and the first end surface LS1 intersect. Therefore, it is possible to increase the contact area between each of the first internal electrode layers 31 and the first external electrode 41, and it is possible to reduce the contact resistance between each of the first internal electrode layers 31 and the first external electrode 41.

Further, the second internal electrode layers 32, more specifically, the extension electrode portions 322, each extends from a portion of the counter electrode portion 321 adjacent to the second end surface LS2 of the multilayer body 10 toward the second end surface LS2 of the multilayer body 10, and is exposed at the second end surface LS2. Thus, the second internal electrode layers 32 and the second external electrode 42 are connected not only to the second main surface TS2, but also to the second end surface LS2 and the ridge portion of the multilayer body 10 where the second main surface TS2 and the second end surface LS2 intersect. Therefore, it is possible to increase the contact area between each of the second internal electrode layers 32 and the second external electrode 42, and it is possible to reduce the contact resistance between each of the second internal electrode layers 32 and the second external electrode 42.

It is preferable that the corner portion of each of the first internal electrode layers 31 is rounded along a ridge portion where the main surface TS1 or TS2 of the multilayer body 10 and the end surface LS1 intersect, and the corner portion of each of the second internal electrode layers 32 is rounded along a ridge portion where the main surface TS1 or TS2 of the multilayer body 10 and the end surface LS2 intersect.

### Modified Example 2

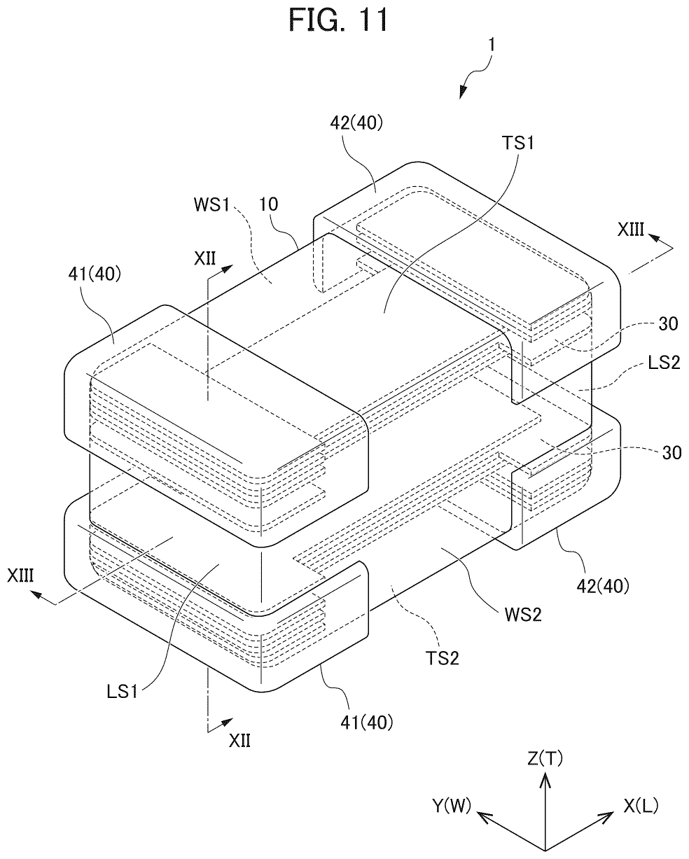

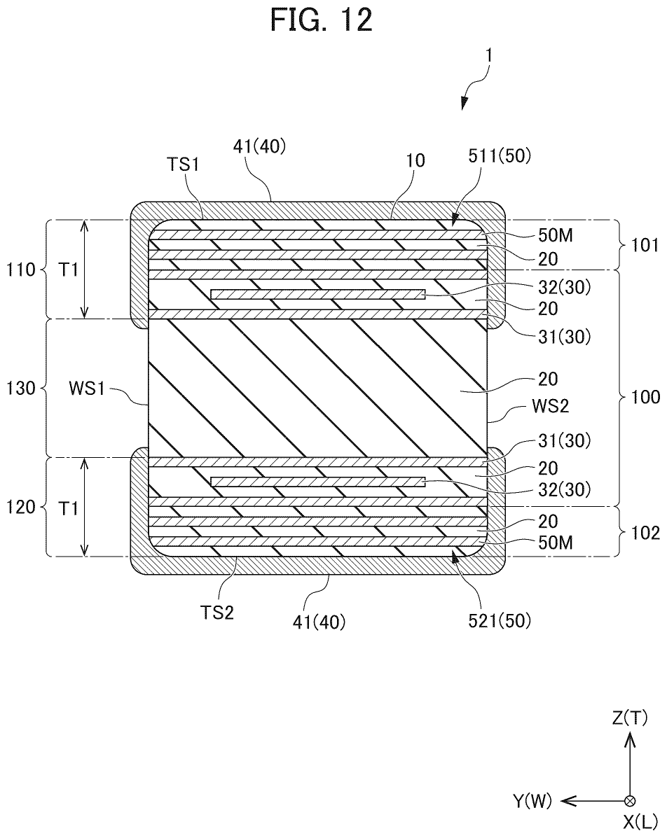

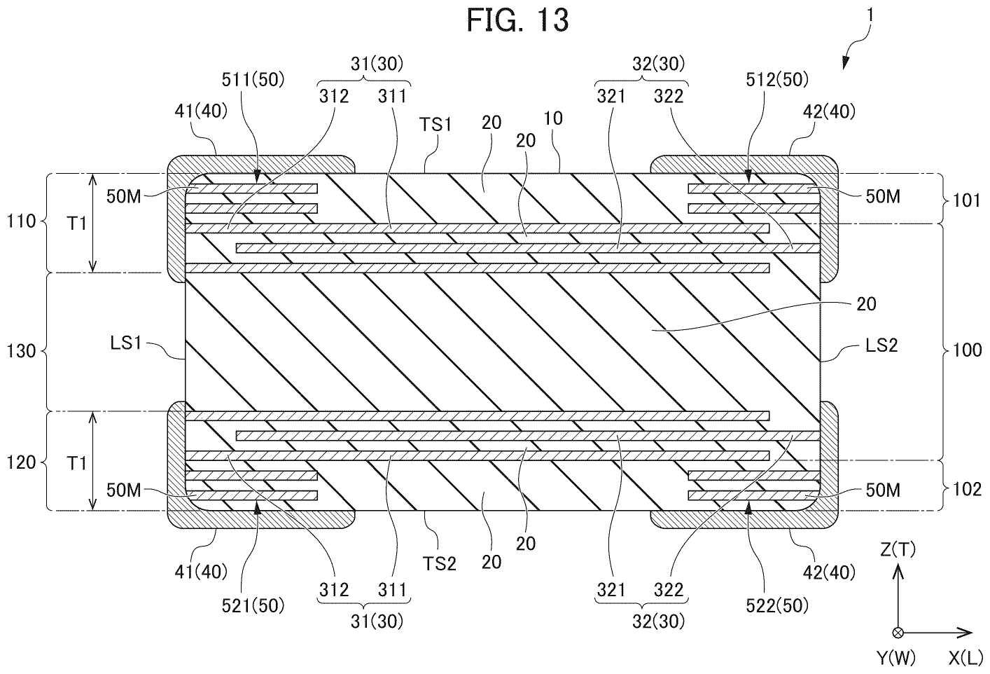

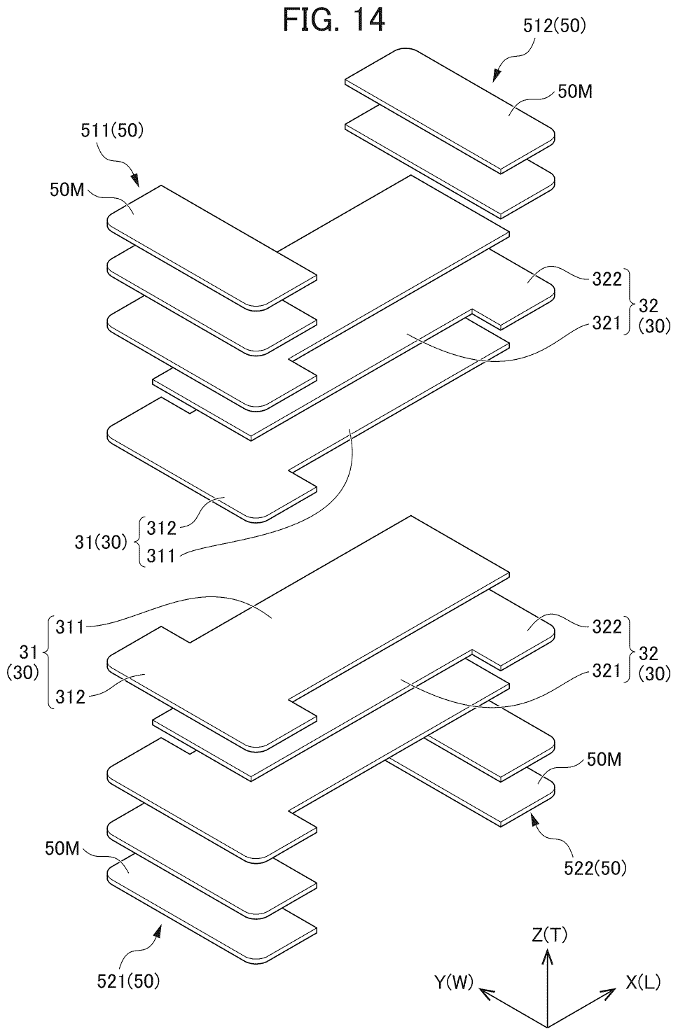

FIG. 11 is a perspective view of a multilayer ceramic capacitor according to a modified example of an example embodiment of the present invention. FIG. 12 is a cross-sectional view taken along the line XII-XII of the multilayer ceramic capacitor shown in FIG. 11. FIG. 13 is a cross-sectional view taken along the line XIII-XIII of the multilayer ceramic capacitor shown in FIG. 11. FIG. 14 is a perspective view of the internal electrode layers in the multilayer ceramic capacitor shown in FIGS. 11 to 13. FIG. 11 shows the internal electrode layers shown in FIG. 14 and one of the two external electrode pairs in a transparent manner.

The multilayer ceramic capacitor 1 shown in FIGS. 11 to 13 is different from the multilayer ceramic capacitor 1 shown in FIGS. 1 to 3B in the shape of two external electrode pairs 40 and the shape of the multilayer body 10.

Specifically, the first external electrode 41 of one of the two external electrode pairs 40 provided on the first main surface TS1 of the multilayer body 10 may extend from the first main surface TS1 to a portion of the first end surface LS1, a portion of the first lateral surface WS1, and a portion of the second lateral surface WS2. The second external electrode 42 of one of the two external electrode pairs 40 may extend from the first main surface TS1 to a portion of the second end surface LS2, a portion of the first lateral surface WS1, and a portion of the second lateral surface WS2. This makes it possible to improve the bonding strength by utilizing the wettability of the solder when mounting on the circuit board.

Similarly, the first external electrode 41 of the other one of the two external electrode pairs 40 provided on the second main surface TS2 of the multilayer body 10 may extend from the second main surface TS2 to a portion of the first end surface LS1, a portion of the first lateral surface WS1, and a portion of the second lateral surface WS2. The second external electrode 42 of the other one of the two external electrode pairs 40 may extend from the second main surface TS2 to a portion of the second end surface LS2, a portion of the first lateral surface WS1, and a portion of the second lateral surface WS2. This makes it possible to improve the bonding strength by utilizing the wettability of the solder when the solder is mounted on the circuit board.

In this case, the internal electrode layers and the external electrode layer can be connected at the end surface and the lateral surfaces of the multilayer body. Therefore, the thickness direction of the multilayer body may be the lamination direction. Specifically, as shown in FIGS. 12 and 13, the multilayer body 10 may include a plurality of dielectric layers 20 and a plurality of internal electrode layers 30 laminated in the thickness direction T. Thus, the multilayer body 10 includes the inner layer portion 100 and the first outer layer portion 101 and the second outer layer portion 102 that sandwich the inner layer portion 100 in the thickness direction T, i.e., the lamination direction.

Further, as in the example embodiments described above, the multilayer body 10 includes the first capacitance portion 110, the second capacitance portion 120, and the non-capacitance portion 130 in the thickness direction T.

The inner layer portion 100 includes a portion of the plurality of dielectric layers 20 and a plurality of internal electrode layers 30. More specifically, the first capacitance portion 110 in the inner layer portion 100 includes a portion of the plurality of dielectric layers 20 and a portion of the plurality of internal electrode layers 30. The second capacitance portion 120 in the inner layer portion 100 includes a portion of the plurality of dielectric layers 20 and a portion of the plurality of internal electrode layers 30 other than a portion for the first capacitance portion 110. In the first capacitance portion 110 and the second capacitance portion 120, adjacent internal electrode layers 30 are opposed to each other with the dielectric layer 20 interposed therebetween. The first capacitance portion 110 and the second capacitance portion 120 are portions that generate capacitance and substantially define and function as capacitors. On the other hand, the non-capacitance portion 130 in the inner layer portion 100 does not include the internal electrode layer 30, and includes a plurality of dielectric layers 20.

The first outer layer portion 101 is provided adjacent to the first main surface TS1 of the multilayer body 10, and the second outer layer portion 102 is provided adjacent to the second main surface TS2 of the multilayer body 10. More specifically, the first outer layer portion 101 is provided between the internal electrode layer 30 closest to the first main surface TS1 among the plurality of internal electrode layers 30 and the first main surface TS1, and the second outer layer portion 102 is provided between the internal electrode layer 30 closest to the second main surface TS2 among the plurality of internal electrode layers 30 and the second main surface TS2. The first outer layer portion 101 and the second outer layer portion 102 do not include the internal electrode layer 30, but include portions of the plurality of dielectric layers 20 other than a portion for the inner layer portion 100. The first outer layer portion 101 and the second outer layer portion 102 respectively define and function as protective layers of the first capacitance portion 110 and the second capacitance portion 120 in the inner layer portion 100.

As shown in FIGS. 12 to 14, each of the first capacitance portion 110 and the second capacitance portion 120 includes a plurality of first internal electrode layers 31 and a plurality of second internal electrode layers 32 as a plurality of internal electrode layers 30. The first internal electrode layers 31 each include the counter electrode portion 311 and the extension electrode portion 312, and the second internal electrode layers 32 each include the counter electrode portion 321 and the extension electrode portion 322.

In the first capacitance portion 110, the counter electrode portions 311 and the counter electrode portions 321 are opposed to each other with the dielectric layer 20 interposed therebetween in the lamination direction of the multilayer body 10, that is, in the thickness direction T. The counter electrode portions 311 and the counter electrode portions 321 are portions which substantially define and function as capacitors to generate capacitances.

In the first capacitance portion 110, the extension electrode portion 312 extends from a portion of the counter electrode portion 311 adjacent to the first end surface LS1 of the multilayer body 10 toward the first end surface LS1, the first lateral surface WS1, and the second lateral surface WS2 of the multilayer body 10, and is exposed at the first end surface LS1, the first lateral surface WS1, and the second lateral surface WS2. The extension electrode portion 322 extends from a portion of the counter electrode portion 321 adjacent to the second end surface LS2 of the multilayer body 10 toward the second end surface LS2, the first lateral surface WS1, and the second lateral surface WS2 of the multilayer body 10, and is exposed at the second end surface LS2, the first lateral surface WS1, and the second lateral surface WS2.

With such a configuration, in the first capacitance portion 110, the first internal electrode layers 31 are connected to the first external electrode 41 of one of the two external electrode pairs 40 provided adjacent to the first main surface TS1 of the multilayer body 10, at the first end surface LS1, the first lateral surface WS1, the second lateral surface WS2, and the ridge portion of the multilayer body 10 where the end surface LS1 and the lateral surfaces WS1 and WS2 intersect. Further, the second internal electrode layers 32 are connected to the second external electrode 42 of one of the two external electrode pairs 40 provided adjacent to the first main surface TS1 of the multilayer body 10, at the second end surface LS2, the first lateral surface WS1, the second lateral surface WS2, and the ridge portion of the multilayer body 10 where the end surface LS2 and the lateral surfaces WS1 and WS2 intersect.

Similarly, in the second capacitance portion 120, the extension electrode portions 312 each extend from a portion of the counter electrode portion 311 adjacent to the first end surface LS1 of the multilayer body 10 toward the first end surface LS1, the first lateral surface WS1, and the second lateral surface WS2 of the multilayer body 10, and is exposed at the first end surface LS1, the first lateral surface WS1, and the second lateral surface WS2. The extension electrode portions 322 each extend from a portion of the counter electrode portion 321 adjacent to the second end surface LS2 of the multilayer body 10 toward the second end surface LS2, the first lateral surface WS1, and the second lateral surface WS2 of the multilayer body 10, and is exposed at the second end surface LS2, the first lateral surface WS1, and the second lateral surface WS2.

Thus, in the second capacitance portion 120, the first internal electrode layers 31 are connected to the first external electrode 41 of one of the external electrode pairs 40 provided adjacent to the second main surface TS2 of the multilayer body 10, at the first end surface LS1, the first lateral surface WS1, the second lateral surface WS2, and the ridge portion of the multilayer body 10 where the end surface LS1 and the lateral surfaces WS1 and WS2 intersect. Further, the second internal electrode layers 32 are connected to the second external electrode 42 of the one of the external electrode pairs 40 provided adjacent to the second main surface TS2 of the multilayer body 10, at the second end surface LS2, the first lateral surface WS1, the second lateral surface WS2, and the ridge portion of the multilayer body 10 where the end surface LS2 and the lateral surfaces WS1 and WS2 intersect.

It is preferable that the corner portion of each of the first internal electrode layers 31 is rounded along a ridge portion where the end surface LS1 and the lateral surfaces WS1 and WS2 of the multilayer body 10 intersect, and the corner portion of each of the second internal electrode layers 32 is rounded along a ridge portion where the end surface LS2 and the lateral surface WS1 or WS2 of the multilayer body 10 intersect.

The plurality of internal electrode layers 30 in the first capacitance portion 110 and the plurality of internal electrode layers 30 in the second capacitance portion 120 may be plane symmetrical with respect to the middle in the thickness direction T. Alternatively, the plurality of internal electrode layers 30 in the first capacitance portion 110 and the plurality of internal electrode layers 30 in the second capacitance portion 120 may be rotationally symmetrical with respect to the middle in the thickness direction T and the middle in the width direction W. When the thickness in the width direction W of the first outer layer portion 101 and the thickness in the width direction W of the second outer layer portion 102 are different, the plurality of internal electrode layers 30 in the first capacitance portion 110 and the plurality of internal electrode layers 30 in the second capacitance portion 120 may be plane symmetrical with respect to the middle in the thickness direction T of the inner layer portion 100 of the multilayer body 10, or alternatively may be rotationally symmetrical with respect to the middle in the thickness direction T of the inner layer portion 100 of the multilayer body 10 and the middle in the width direction W of the multilayer body 10.

The thickness T1 of the internal electrode layers 30 in the thickness direction T of the first capacitance portion 110, in other words, the thickness T1 of the internal electrode layers 30 in the first capacitance portion 110 from the first main surface TS1, is preferably, for example, about 25 μm or more and about 70 μm or less. The thickness T1 of the internal electrode layers 30 in the thickness direction T of the second capacitance portion 120, in other words, the thickness T1 of the internal electrode layers 30 in the second capacitance portion 120 from the second main surface TS2, is preferably, for example, about 25 μm or more and about 70 μm or less.

The thickness of each of the first internal electrode layers 31 and the second internal electrode layers 32 is not particularly limited, but are preferably, for example, about 0.4 μm or more and about 2.0 μm or less. The number of the first internal electrode layers 31 and the second internal electrode layers 32 is not particularly limited, but is preferably, for example, 2 or more and 35 or less.

Further, the first outer layer portion 101 and the second outer layer portion 102 each may include a plurality of conductor portions 50. The plurality of conductor portions 50 include first conductor portions 511 and 512 and second conductor portions 521 and 522.

The first conductor portion 511 is provided adjacent to the first end surface LS1 of the first outer layer portion 101, and the first conductor portion 512 is provided adjacent to the second end surface LS2 of the first outer layer portion 101. Further, the second conductor portion 521 is provided adjacent to the first end surface LS1 of the second outer layer portion 102, and the second conductor portion 522 is provided adjacent to the second end surface LS2 of the second outer layer portion 102.

Each of the first conductor portions 511 and 512 and the second conductor portions 521 and 522 includes a plurality of conductor layers 50M. The shape of the conductor layers 50M is not particularly limited, and may have, for example, a rectangular or substantially rectangular shape. The plurality of conductor layers 50M are laminated with the dielectric layer 20 interposed therebetween in the thickness direction T, i.e., the lamination direction.

An end portion of each of the conductor layers 50M of the first conductor portion 511 is exposed at the first end surface LS1, the first lateral surface WS1, and the second lateral surface WS2. With such a configuration, the end portion of each of the conductor layers 50M of the first conductor portion 511 is connected to the first external electrode 41 of one of the two external electrode pairs 40 provided on the first main surface TS1 of the multilayer body 10, at the first end surface LS1, the first lateral surface WS1, the second lateral surface WS2, and the ridge portion of the multilayer body 10 where the end surface LS1 and the lateral surfaces WS1 and WS2 intersect. Further, the end portion of each of the conductor layers 50M of the first conductor portion 512 is exposed at the second end surface LS2, the first lateral surface WS1, and the second lateral surface WS2. With such a configuration, the end portion of each of the conductor layers 50M of the first conductor portion 512 is connected to the second external electrode 42 of one of the two external electrode pairs 40 provided adjacent to the first main surface TS1 of the multilayer body 10, at the second end surface LS2, the first lateral surface WS1, the second lateral surface WS2, and the ridge portion of the multilayer body 10 where the end surface LS2 and the lateral surfaces WS1 and WS2 intersect.

Similarly, the end portion of each of the conductor layers 50M of the second conductor portion 521 is exposed at the first end surface LS1, the first lateral surface WS1, and the second lateral surface WS2. With such a configuration, the end portion of each of the conductor layers 50M of the second conductor portion 521 is connected to the first external electrode 41 of one of the two external electrode pairs 40 provided on the second main surface TS2 of the multilayer body 10, at the first end surface LS1, the first lateral surface WS1, the second lateral surface WS2, and the ridge portion of the multilayer body 10 where the end surface LS1 and the lateral surfaces WS1 and WS2 intersect. Further, the end portion of each of the conductor layers 50M of the second conductor portion 522 is exposed at the second end surface LS2, the first lateral surface WS1, and the second lateral surface WS2. With such a configuration, the end portion of the conductor layers 50M of the second conductor portion 522 is connected to the second external electrode 42 of one of the two external electrode pairs 40 provided on the second main surface TS2 of the multilayer body 10, at the second end surface LS2, the first lateral surface WS1, the second lateral surface WS2, and the ridge portion of the multilayer body 10 where the end surface LS2 and the lateral surfaces WS1 and WS2 intersect.

The corner of each of the conductor layers 50M is preferably rounded along a ridge portion where the end surface LS1 and the lateral surfaces WS1 and WS2 of the multilayer body 10 intersect, or a ridge portion where the end surface LS2 and the lateral surface WS1 or WS2 of the multilayer body 10 intersect.

The material of each of the conductor layers 50M is not particularly limited, but includes, for example, the same material as the internal electrode layers 30. The thickness of each of the plurality of conductor layers 50M is not particularly limited, but is preferably, for example, about 0.2 μm or more and about 1.0 μm or less. In each of the first conductor portions 511 and 512 and the second conductor portions 521 and 522, the number of the plurality of conductor layers 50M is not particularly limited, but is preferably, for example, 2 or more and 30 or less.

By providing the conductor layers 50M in this manner, it is possible to improve the adhesion of the external electrode pairs 40 to the multilayer body 10. In particular, when the external electrode pairs 40 include only plating, the conductor layers 50M define and function as a plating growth starting point.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer ceramic capacitor comprising:
a multilayer body including a plurality of dielectric layers including a ceramic material and a plurality of internal electrode layers laminated therein, two main surfaces opposed to each other in a thickness direction, two lateral surfaces opposed to each other in a width direction intersecting the thickness direction, and two end surfaces opposed to each other in a length direction intersecting the thickness direction and the width direction; and
two external electrode pairs each provided on a corresponding one of the two main surfaces of the multilayer body; wherein
the multilayer body includes:
a first capacitance portion including a first portion of the plurality of internal electrode layers and in which adjacent internal electrode layers of the first portion of the plurality of internal electrode layers are opposed to each other; and
a second capacitance portion including a second portion other than the first portion of the plurality of internal electrode layers and in which adjacent internal electrode layers of the second portion of the plurality of internal electrode layers are opposed to each other;
the first portion of the plurality of internal electrode layers in the first capacitance portion is connected to a first of the two external electrode pairs; and
the second portion of the plurality of internal electrode layers in the second capacitance portion is connected to a second of the two external electrode pairs.

2. The multilayer ceramic capacitor according to claim 1, wherein the two external electrode pairs each include a metal layer including plating.

3. The multilayer ceramic capacitor according to claim 1, wherein the first portion of the plurality of internal electrode layers in the first capacitance portion and the second portion of the plurality of internal electrode layers in the second capacitance portion are plane symmetrical with respect to a middle of the multilayer body in the thickness direction.

4. The multilayer ceramic capacitor according to claim 1, wherein the first portion of the plurality of internal electrode layers in the first capacitance portion and the second portion of the plurality of internal electrode layers in the second capacitance portion are rotationally symmetrical with respect to a middle of the multilayer body in the thickness direction.

5. The multilayer ceramic capacitor according to claim 1, wherein a thickness of each of the first portion of the plurality of internal electrode layers in the first capacitance portion and the second portion of the plurality of internal electrode layers in the second capacitance portion in the thickness direction is about 25 μm or more and about 70 μm or less.

6. The multilayer ceramic capacitor according to claim 1, wherein each of the plurality of dielectric layers includes a dielectric ceramic including at least one of BaTiO₃, CaTiO₃, SrTiO₃, or CaZrO₃ as a main component.

7. The multilayer ceramic capacitor according to claim 6, wherein each of the plurality of dielectric layers includes at least one of a Mn compound, a Fe compound, a Cr compound, a Co compound, or a Ni compound as a subcomponent.

8. The multilayer ceramic capacitor according to claim 1, wherein a thickness of each of the plurality of dielectric layers is about 0.4 μm or more and about 2.0 μm or less.

9. The multilayer ceramic capacitor according to claim 1, wherein each of the plurality of internal electrode layers includes metal Ni as a main component.

10. The multilayer ceramic capacitor according to claim 1, wherein a thickness of each of the plurality of internal electrode layers is about 0.2 μm or more and about 1.0 μm or less.

11. A circuit module comprising:
a circuit board including electronic circuit components mounted thereon;
a multilayer ceramic capacitor according to claim 1, the multilayer ceramic capacitor being one of the electronic circuit components mounted on the circuit board; and
a resin mold provided around the multilayer ceramic capacitor; wherein
a portion of the multilayer ceramic capacitor in a thickness direction is removed such that the multilayer ceramic capacitor includes either one of a first capacitance portion or a second capacitance portion; and
a surface roughness of one of the two main surfaces of the multilayer ceramic capacitor opposite to the circuit board is larger than a surface roughness of the multilayer body of the multilayer ceramic capacitor opposed to the resin mold.

12. The circuit module according to claim 11, wherein the two external electrode pairs each include a metal layer including plating.

13. The circuit module according to claim 11, wherein the first portion of the plurality of internal electrode layers in the first capacitance portion and the second portion of the plurality of internal electrode layers in the second capacitance portion are plane symmetrical with respect to a middle of the multilayer body in the thickness direction.

14. The circuit module according to claim 11, wherein the first portion of the plurality of internal electrode layers in the first capacitance portion and the second portion of the plurality of internal electrode layers in the second capacitance portion are rotationally symmetrical with respect to a middle of the multilayer body in the thickness direction.

15. The circuit module according to claim 11, wherein a thickness of each of the first portion of the plurality of internal electrode layers in the first capacitance portion and the second portion of the plurality of internal electrode layers in the second capacitance portion in the thickness direction is about 25 μm or more and about 70 μm or less.

16. The circuit module according to claim 11, wherein each of the plurality of dielectric layers includes a dielectric ceramic including at least one of BaTiO₃, CaTiO₃, SrTiO₃, or CaZrO₃ as a main component.

17. The circuit module according to claim 16, wherein each of the plurality of dielectric layers includes at least one of a Mn compound, a Fe compound, a Cr compound, a Co compound, or a Ni compound as a subcomponent.

18. The circuit module according to claim 11, wherein a thickness of each of the plurality of dielectric layers is about 0.4 μm or more and about 2.0 μm or less.

19. The circuit module according to claim 11, wherein each of the plurality of internal electrode layers includes metal Ni as a main component.

20. A method of manufacturing a circuit module according to claim 11, the method comprising:
mounting the multilayer ceramic capacitor included in electronic circuit components on a circuit board;
filling an area around the multilayer ceramic capacitor with the resin mold; and
polishing the multilayer ceramic capacitor and the resin mold in the thickness direction.
